(19) United States
(12) Patent Application Publication
(10) Pub. No.: US 2026/0181942 A1
(43) Pub. Date: Jun. 25, 2026

(54) METHOD FOR PROCESSING INPUT VARIABLES USING A PROCESSING DEVICE HAVING AT LEAST ONE FIELD-EFFECT TRANSISTOR, DEVICE FOR CARRYING OUT THE METHOD, COMPUTING DEVICE AND USE

(71) Applicant: Robert Bosch GmbH, Stuttgart (DE)

(72) Inventors: Taha Soliman, Renningen (DE); Tobias Kirchner, Ludwigsburg (DE)

(21) Appl. No.: 19/127,580

(22) PCT Filed: Jan. 23, 2024
(86) PCT No.: PCT/EP2024/051549

§ 371 Date: May 6, 2025

(30) Foreign Application Priority Data
Jan. 30, 2023 (DE) 10 2023 200 722.3

(51) Int. Cl. H10D 30/60; H10D 30/01; H10D 30/67; H10D 64/01; H10D 84/80

(52) U.S. Cl. CPC H10D 30/611; H10D 30/025; H10D 30/6757; H10D 64/01; H10D 64/017; H10D 84/811

(57) ABSTRACT

A method for processing input variables using a processing device having at least one first field-effect transistor. The method includes: providing the first field-effect transistor with a first threshold voltage, which characterizes a first input variable associated with the first field-effect transistor; applying to a gate electrode of the first field-effect transistor a first control variable, which characterizes a second input variable associated with the first field-effect transistor; ascertaining a first output variable, which characterizes at least one product of the first input variable and the second input variable, on the basis of a first variable, which characterizes a time profile of a current through a load path of the first field-effect transistor.

### FIELD

The present invention relates to a method for processing input variables using a processing device having at least one first field-effect transistor, for example a ferroelectric field-effect transistor.

The present invention further relates to a device for carrying out a method for processing input variables using a processing device having at least one first field-effect transistor, for example a ferroelectric field-effect transistor.

### SUMMARY

Exemplary embodiments of the present invention relate to a method for processing input variables using a processing device having at least one first field-effect transistor, for example a ferroelectric field-effect transistor (FeFET), comprising: providing the first field-effect transistor with a first threshold voltage, which characterizes a first input variable associated with the first field-effect transistor; applying to a gate electrode of the first field-effect transistor a first control variable, which characterizes a second input variable associated with the first field-effect transistor; ascertaining a first output variable, which characterizes at least one product of the first input variable and of the second input variable, on the basis of a first variable, which characterizes a time profile of a current through a load path of the first field-effect transistor. In further exemplary embodiments, a product of the first input variable and of the second input variable can thus, for example, be ascertained using the field-effect transistor, wherein at least one of the two input variables can be analog (i.e., for example, continuous-value).

In further exemplary embodiments of the present invention, it is provided that the first variable is at least one of the following elements: a) the current through the load path itself; b) a voltage that can be ascertained on the basis of at least the current through the load path. For example, in further exemplary embodiments, a capacitor can be charged with the current through the load path, wherein, for example, the voltage of the capacitor or its time profile forms the first variable.

In further exemplary embodiments of the present invention, it is provided that the method comprises: programming the first field-effect transistor (e.g., formed as FeFET) to the first threshold voltage on the basis of the first input variable, for example by means of an optional programming device, and, optionally, using the programmed first field-effect transistor. For example, the first input variable or a value of the first input variable can be specified, and the threshold voltage of the FeFET can be programmed on the basis of the first input variable or the value thereof, for example using a conventional programming method. In further exemplary embodiments, for example, a position of a characteristic curve indicating a drain current with respect to a gate-source voltage can be changed by programming, for example shifted along the gate-source voltage coordinate.

Although the principle according to the example embodiments of the present invention is not limited to ferroelectric field-effect transistors (FeFETs), for the sake of clarity, and without restricting generality, the following exemplary embodiments relate primarily to field-effect transistors designed as FeFETs.

In further exemplary embodiments of the present invention, it is provided that the method comprises: providing a charging current for charging a capacitance associated with the gate electrode of the first field-effect transistor, for example an intrinsic and/or parasitic capacitance, for example a Miller capacitance, for example by means of a charging device. As an alternative or in addition to the, for example intrinsic, Miller capacitance, in further exemplary embodiments of the gate electrode, a further capacitance can be assigned, for example for setting a specifiable capacitance value. In further exemplary embodiments, it is also possible to adjust the intrinsic capacitance within the framework of manufacturing conditions during a manufacturing process. In further exemplary embodiments, a defined activation of the FeFET, i.e., for example, moving the FeFET from a blocking (high-impedance) state to a conductive (low-impedance) state, is possible by charging the above-described capacitance, wherein, for example, a time behavior for the charging can inter alia be determined by the aforementioned capacitance and/or an optionally present intrinsic resistance, for example of the gate electrode.

In further exemplary embodiments of the present invention, it is provided that the method comprises: providing an input voltage on the basis of the second input variable; applying the input voltage to the gate electrode of the first field-effect transistor via a specifiable resistance; and, optionally, at least periodically charging a, for example the, capacitance associated with the gate electrode of the first field-effect transistor. In further exemplary embodiments, the time behavior for charging the capacitance (and thus, for example, for putting the load path of the FeFET into a low-impedance state) can be set by charging via the specifiable resistance. In addition, the time behavior for charging depends on the input voltage, which can be selected, for example, on the basis of the second input variable.

In further exemplary embodiments of the present invention, it is provided that the method comprises: ascertaining a first point in time, at which the current through the load path of the first field-effect transistor exceeds a specifiable first threshold value (for example, considered from the charging of the capacitance associated with the gate electrode of the first field-effect transistor); ascertaining the first output variable on the basis of the first point in time.

In other words, using the principle according to the example embodiments of the present invention, for example, a multiplication a*b=c (* is the (scalar) multiplication operator) can be evaluated using the FeFET, wherein the factor a corresponds, for example, to the first input variable (for example, programming the FeFET to a threshold voltage corresponding to the factor a), and wherein the factor b corresponds, for example, to the second input variable (for example, the input voltage for charging the capacitance associated with the gate electrode of the first field-effect transistor).

For example, in further exemplary embodiments of the present invention, for comparatively small values of the first factor a, a comparatively high threshold voltage can be programmed for the first FeFET so that, in a charging process considered by way of example of the capacitance associated with the gate electrode of the first FeFET, the load path becomes conductive comparatively late, and the first point in time, at which the current through the load path of the first FeFET exceeds the specifiable first threshold value, is thus comparatively late, relative to a start of the charging process.

In contrast, in further exemplary embodiments of the present invention, for comparatively large values of the first factor a, a comparatively low threshold voltage can be programmed for the first FeFET so that, in a charging process considered by way of example of the capacitance associated with the gate electrode of the first FeFET, the load path becomes conductive comparatively early, and the first point in time, at which the current through the load path of the first FeFET exceeds the specifiable first threshold value, is thus comparatively early, relative to a start of the charging process.

For example, in further exemplary embodiments of the present invention, for comparatively small values of the second factor b, a comparatively low input voltage can be selected for the charging process of the capacitance associated with the gate electrode of the first FeFET, which causes a comparatively small temporal change in the gate-source voltage during the charging process and thus also causes a comparatively late exceeding of the first threshold value, for example similarly to a comparatively high threshold voltage.

For example, in further exemplary embodiments of the present invention, for comparatively large values of the second factor b, a comparatively high input voltage can be selected for the charging process of the capacitance associated with the gate electrode of the first FeFET, which causes a comparatively large temporal change in the gate-source voltage during the charging process and thus also causes a comparatively early exceeding of the first threshold value, for example similarly to a comparatively low threshold voltage.

In further exemplary embodiments of the present invention, a specifiable value for the result of the multiplication a*b=c, i.e., for the product c, can accordingly be assigned to the first point in time, at which the current through the load path of the first FeFET exceeds the specifiable first threshold value. In further exemplary embodiments, different result values for the product c can be assigned in a comparable manner to different points in time, for example calculated after the start of the charging process, so that, in further exemplary embodiments, for example on the basis of a specific value of the first point in time, the corresponding result value for the product c can be deduced.

In other words, in further exemplary embodiments of the present invention, a time measurement can be carried out, on the basis of which the product c can be ascertained. This is advantageous in further exemplary embodiments since the time measurement can be carried out very efficiently and/or precisely with currently available technology.

In further exemplary embodiments of the present invention, the specifiable first threshold value corresponds to at least one of the following elements: a) saturation current of the first field-effect transistor; b) limit current, to which the current through the load path of the first field-effect transistor can be limited and/or is limited, for example by means of at least one limiting resistor connected in series with the load path; c) any specifiable current value.

In further exemplary embodiments of the present invention, it is provided that the method comprises: ascertaining a first time difference between a start of the application of the first control variable (e.g., corresponding to a start of the charging process) to the gate electrode of the first field-effect transistor and the first point in time, at which the current through the load path of the first field-effect transistor exceeds the specifiable first threshold value; and ascertaining the first output variable on the basis of the first time difference, for example using an assignment of possible time differences to possible multiplication results c=a*b.

In further exemplary embodiments of the present invention, it is provided that the method comprises: limiting the current through the load path of the first field-effect transistor by means of at least one limiting resistor connected in series with the load path. In further exemplary embodiments, the limiting resistor can be selected, for example, such that, for example in the switched-on state of the FeFET, the current through the load path is between, for example about, 10 nA (nanoamperes) and, for example about, 1000 nA, for example about 100 nA. This causes, for example, the current through the load path of the first FeFET to increase from, for example, 0 to the aforementioned 100 nA during the charging process, with a time behavior determined by the two input variables E1, E2 or the configuration based thereon (e.g., programming of the threshold voltage of the FeFET, selection of the input voltage for charging).

In further exemplary embodiments of the present invention, it is provided that the processing device has at least one further field-effect transistor, for example a ferroelectric field-effect transistor, wherein a corresponding first terminal of a load path of the first field-effect transistor and of the at least one further field-effect transistor is connected to a first circuit node, wherein the method comprises: providing the at least one further field-effect transistor with a corresponding further threshold voltage, which characterizes a first input variable associated with the corresponding further field-effect transistor; applying to a corresponding gate electrode of the at least one further field-effect transistor a corresponding first control variable, which characterizes a second input variable associated with the corresponding further field-effect transistor; ascertaining the first output variable, which characterizes, for example, a sum of respective products of the corresponding first input variable and of the corresponding second input variable, on the basis of a second variable, which characterizes a time profile of a current associated with the first circuit node, wherein, for example, the second variable is at least one of the following elements: a) the current itself associated with the first circuit node; b) a voltage which can be ascertained on the basis of at least the current associated with the first circuit node. In further exemplary embodiments, for example, a calculation of the MAC (multiply and accumulate) type is thereby made possible, wherein the first field-effect transistor and the at least one further, e.g., second, field-effect transistor, for example, in each case carry out a multiplication, for example analogously to the embodiments described above by way of example. An accumulation, for example addition, takes place here, for example, by the respective load paths of the two field-effect transistors being connected to the first circuit node, namely, for example, by an addition of the currents of the two field-effect transistors. For example, in the above-mentioned configuration, a first product c1=a1*b1 can be ascertained by the first field-effect transistor on the basis of the factors a1, b1 (which can, for example, be realized by programming a corresponding threshold voltage and/or specifying a corresponding input voltage for charging, for example, the intrinsic capacitance of the first field-effect transistor), and a second product c2=a2*b2 can be ascertained by the second field-effect transistor on the basis of the factors a2, b2 (which can, for example, be realized by programming a corresponding threshold voltage and/or specifying a corresponding input voltage for charging, for example, the intrinsic capacitance of the second field-effect transistor), wherein an accumulation, for example addition, c1+c2 can be carried out by the combination of the respective load currents through the load paths of the two field-effect transistors in the first circuit node. Even in the exemplary embodiments with more than one field-effect transistor, the result c1+c2 of the MAC calculation can be deduced on the basis of the second variable and a possibly effected assignment of points in time at which one or more corresponding threshold values are exceeded by the second variable.

In further exemplary embodiments of the present invention, it is provided that the processing device comprises n, n>1, field-effect transistors, for example ferroelectric field-effect transistors, wherein a corresponding first terminal of a load path of the n field-effect transistors is connected to a, for example the, first circuit node, wherein the method comprises: providing a k-th field-effect transistor, k=1, . . . , n, (for example all n field-effect transistors) with a k-th threshold voltage (for example by optional programming, for example in the case of FeFETs), which characterizes a corresponding first input variable associated with the k-th field-effect transistor; applying to a gate electrode of the k-th field-effect transistor (for example of all n field-effect transistors) a k-th control variable, which characterizes a corresponding second input variable associated with the k-th field-effect transistor; ascertaining the first output variable, which characterizes, for example, a sum of k products of the corresponding first input variable and the corresponding second input variable, on the basis of a or the second variable, which characterizes the time profile of the current associated with the first circuit node. In further exemplary embodiments, the principle according to the embodiments can thus be extended to any number n of field-effect transistors so that, for example, MAC calculations are possible, which makes possible a formation of, for example maximally, n products and an accumulation of the, for example maximally, n products. In further exemplary embodiments, such calculations can be used, for example, for the evaluation (inference) of artificial (deep) neural networks ((D)NN). Further possible applications according to further exemplary embodiments are described below with reference to FIG. 22.

In further exemplary embodiments of the present invention, it is provided that the method comprises: starting the application of the k-th control variable to the gate electrode of the k-th field-effect transistor (for example of all n field-effect transistors) at a starting point in time (for example common to all n field-effect transistors); repeatedly, for example periodically, for example continuously, ascertaining the second variable, for example during a specifiable time period from the starting point in time.

In further exemplary embodiments of the present invention, it is provided that the method comprises: ascertaining changes in the second variable at specifiable points in time, wherein, for example, the specifiable points in time are in each case associated with possible values for the corresponding first input variable and/or for the corresponding second input variable; weighting the ascertained changes in the second variable, wherein weighted changes are obtained; and, optionally, ascertaining the first output variable by summing the weighted changes in the second variable.

In further exemplary embodiments of the present invention, changes which are associated with a transition of at least one of the used field-effect transistors from a high-impedance state to a low-impedance state can, for example, be considered changes in the second variable which are to be ascertained. If, for example, a maximum current through a load path of at least one of the field-effect transistors used is 100 nA, then, in further exemplary embodiments, a change in the second variable in the range of approximately 100 nA can be taken into account. In further exemplary embodiments, changes in the second variable which, for example, are significantly less than 100 nA can remain disregarded, for example if none of the field-effect transistors used has a correspondingly lower maximum current than the 100 nA mentioned.

In further exemplary embodiments of the present invention, it is provided that the method comprises: repeating the ascertainment and weighting, for example until a specifiable termination criterion is met.

In further exemplary embodiments of the present invention, the termination criterion is an elapsing of a specifiable maximum measuring time, for example specifiable on the basis of a number of field-effect transistors used and/or on the corresponding first and/or second input variable of at least one of the field-effect transistors used.

In further exemplary embodiments of the present invention, the termination criterion depends on a time profile of the gate-source voltage of a field-effect transistor having the smallest slope (e.g., due to a comparatively high threshold voltage (e.g., corresponding to a comparatively small first input variable) and/or due to a comparatively low input voltage (e.g., corresponding to a comparatively small second input variable)).

In further exemplary embodiments of the present invention, the termination criterion is met when the second variable has a maximum value dependent, for example, on the configuration (for example, number of field-effect transistors) of the processing device (for example, maximum current at the first node corresponds, for example, to a state in which all field-effect transistors are low-impedance).

In further exemplary embodiments of the present invention, it is provided that the method comprises: assigning the specifiable points in time (for example, associated with the changes in the second variable) to possible values for the corresponding first input variable and/or for the corresponding second input variable.

Further exemplary embodiments of the present invention relate to a device for carrying out the method according to the embodiments of the present invention.

In further exemplary embodiments of the present invention, it is provided that the device has a processing device having at least a first field-effect transistor, for example a ferroelectric field-effect transistor, wherein, for example, the processing device has n, n>1, field-effect transistors, for example ferroelectric field-effect transistors.

In further exemplary embodiments of the present invention, it is provided that the device has a programming device for programming the at least one first field-effect transistor, for example FeFET, to a specifiable threshold voltage.

In further exemplary embodiments of the present invention, it is provided that the device has at least one charging device for providing a charging current for the at least one first field-effect transistor, for example for a plurality of, for example all, field-effect transistors.

In further exemplary embodiments of the present invention, it is provided that the device has at least one measuring device, for example a, for example current-based, analog-to-digital converter, for ascertaining at least one of the following variables: a) first variable; b) second variable.

In further exemplary embodiments of the present invention, it is provided that the device has a control device, which is designed to execute at least one of the following elements: a) control of at least one component of the device; b) execution of at least one aspect of the method according to the embodiments.

Further exemplary embodiments of the present invention relate to a computing device, for example a vector-matrix multiplication device, comprising at least one device according to the embodiments of the present invention.

Further exemplary embodiments of the present invention relate to a use of the method according to the embodiments of the present invention and/or of the device according to the embodiments of the present invention and/or of the computing device according to the embodiments of the present invention for at least one of the following elements: a) execution of compute-in-memory methods, for example with weights and/or input variables, which can, for example in each case, have a plurality of bits; b) artificial neural networks, for example artificial deep neural networks; c) image processing; d) efficient execution of calculations; e) increasing an efficiency for the execution of calculations; f) automated driving; g) machine learning, for example inference.

Further features, possible applications and advantages of the present invention will be apparent from the following description of exemplary embodiments of the present invention shown in the figures. In this case, all of the features described or shown form the subject matter of the present invention individually or in any combination, irrespective of their wording or representation in the description herein or in the figures.

### BRIEF DESCRIPTION OF THE DRAWINGS

FIG. 1 schematically shows a simplified flowchart according to exemplary embodiments of the present invention.

FIG. 2 schematically shows a simplified block diagram according to further exemplary embodiments of the present invention.

FIG. 3 schematically shows a simplified flowchart according to further exemplary embodiments of the present invention.

FIG. 4 schematically shows a simplified flowchart according to further exemplary embodiments of the present invention.

FIG. 5 schematically shows a simplified block diagram according to further exemplary embodiments of the present invention.

FIG. 6 schematically shows a simplified flowchart according to further exemplary embodiments of the present invention.

FIG. 7 schematically shows a simplified block diagram according to further exemplary embodiments of the present invention.

FIG. 8 schematically shows a simplified flowchart according to further exemplary embodiments of the present invention.

FIG. 9 schematically shows a simplified flowchart according to further exemplary embodiments of the present invention.

FIG. 10A schematically shows a simplified circuit diagram according to further exemplary embodiments of the present invention.

FIG. 10B schematically shows a simplified circuit diagram according to further exemplary embodiments of the present invention.

FIG. 11A schematically shows currents according to further exemplary embodiments plotted over a gate-source voltage of the present invention.

FIG. 11B schematically shows voltages according to further exemplary embodiments of the present invention plotted over time.

FIG. 11C schematically shows voltages according to further exemplary embodiments of the present invention plotted over time.

FIG. 11D schematically shows currents according to further exemplary embodiments of the present invention plotted over a gate-source voltage.

FIG. 11E schematically shows voltages according to further exemplary embodiments of the present invention plotted over time.

FIG. 11F schematically shows a current according to further exemplary embodiments of the present invention plotted over time.

FIG. 11G schematically shows voltages according to further exemplary embodiments of the present invention plotted over time.

FIG. 12 schematically shows a simplified circuit diagram according to further exemplary embodiments of the present invention.

FIG. 13 schematically shows a simplified flowchart according to further exemplary embodiments of the present invention.

FIG. 14 schematically shows a simplified block diagram according to further exemplary embodiments of the present invention.

FIG. 15 schematically shows a simplified flowchart according to further exemplary embodiments of the present invention.

FIG. 16 schematically shows a simplified flowchart according to further exemplary embodiments of the present invention.

FIG. 17 schematically shows a simplified time diagram according to further exemplary embodiments of the present invention.

FIG. 18 schematically shows a simplified flowchart according to further exemplary embodiments of the present invention.

FIG. 19 schematically shows a simplified flowchart according to further exemplary embodiments of the present invention.

FIG. 20 schematically shows a simplified block diagram according to further exemplary embodiments of the present invention.

FIG. 21 schematically shows a simplified block diagram according to further exemplary embodiments of the present invention.

FIG. 22 schematically shows aspects of uses according to further exemplary embodiments of the present invention.

### DETAILED DESCRIPTION OF EXAMPLE EMBODIMENTS

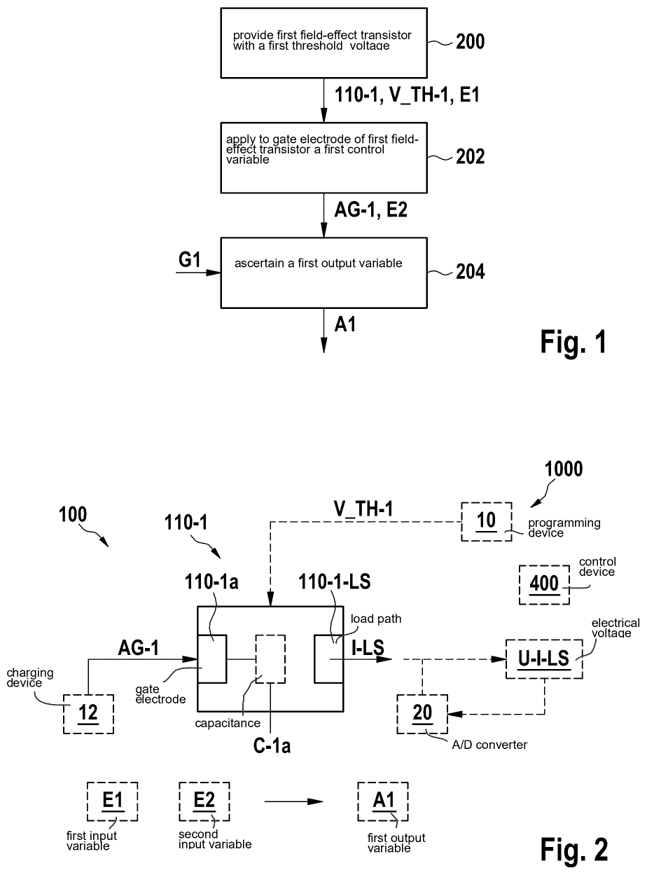

Exemplary embodiments, cf. FIG. 1, 2, relate to a method for processing input variables using a processing device 100 having at least one first field-effect transistor, for example a ferroelectric field-effect transistor (FeFET), 110-1 (FIG. 2), comprising: providing 200 (FIG. 1) the first field-effect transistor 110-1 with a first threshold voltage V_TH-1, which characterizes a first input variable E1 associated with the first field-effect transistor (FET) 110-1; applying 202 to a gate electrode 110-1a (FIG. 2) of the first field-effect transistor 110-1 a first control variable AG-1, which characterizes a second input variable E2 associated with the first field-effect transistor 110-1; ascertaining 204 (FIG. 1) a first output variable A1, which characterizes at least one product (in the sense of the result of a, e.g., scalar, multiplication) of the first input variable E1 and the second input variable E2, on the basis of a first variable G1, which characterizes a time profile of a current I-LS through a load path 110-1-LS of the first field-effect transistor 110-1. In further exemplary embodiments, for example, a product of the first input variable E1 and of the second input variable E2 can thus be ascertained using the first field-effect transistor 110-1, i.e., for example, in a hardware-based manner, for example at least partially according to an “analog computer” principle, wherein at least one of the two input variables E1, E2 can be analog (i.e., for example, continuous-value).

In further exemplary embodiments, it is provided that the first variable G1 is at least one of the following elements: a) the current I-LS through the load path 110-1-LS (drain-source path of the FET) itself; b) a voltage U-I-LS which can be ascertained on the basis of at least the current I-LS through the load path 110-1-LS (FIG. 2). For example, in further exemplary embodiments, a capacitor (not shown) can be charged with the current I-LS through the load path 110-1-LS, wherein, for example, the voltage of the capacitor or its time profile forms the first variable G1.

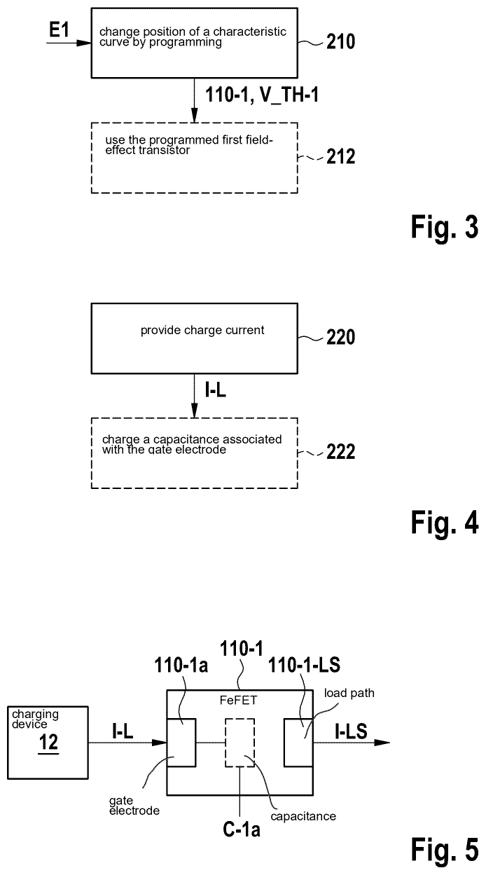

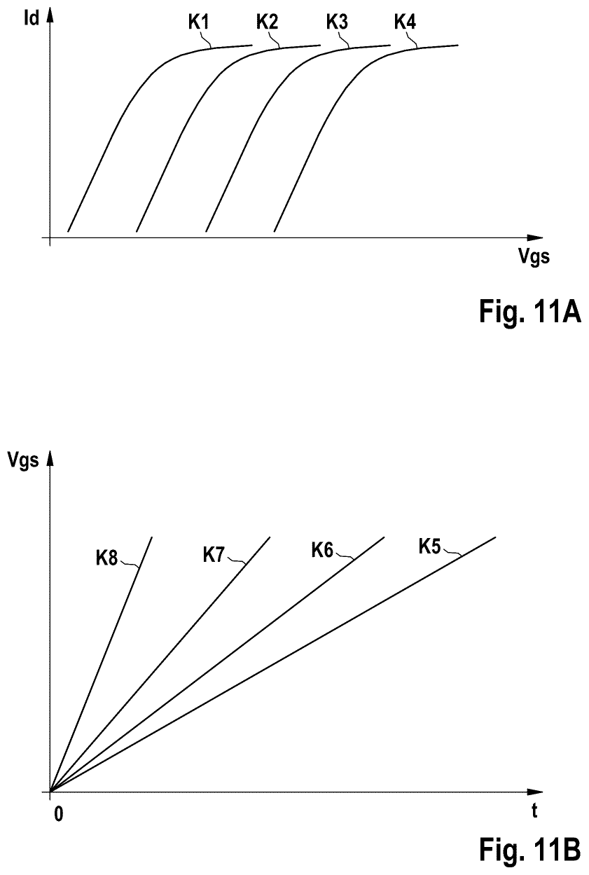

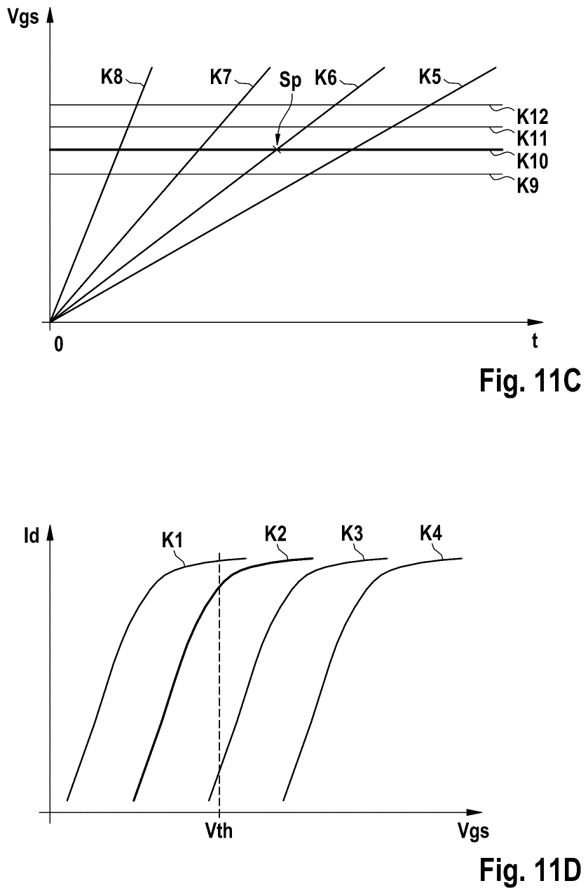

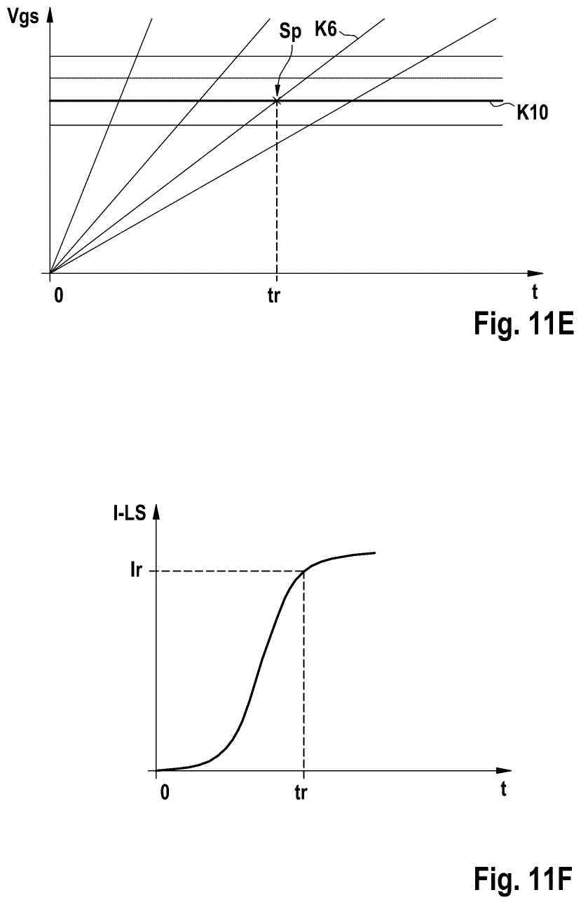

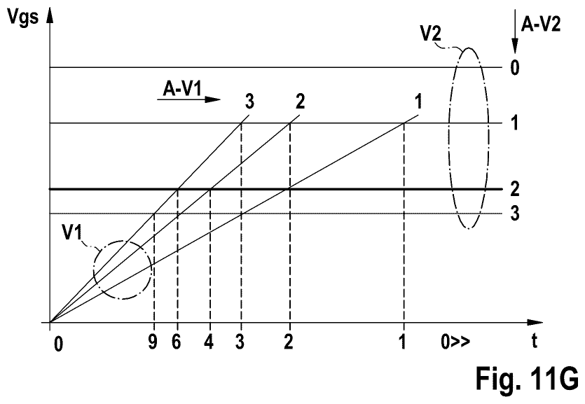

In further exemplary embodiments, FIG. 3, it is provided that the method comprises: programming 210 the first field-effect transistor (e.g., formed as FeFET) to the first threshold voltage V_TH-1 on the basis of the first input variable E1, for example by means of an optional programming device 10 (FIG. 2), and, optionally, using 212 the programmed first field-effect transistor 110-1. For example, the first input variable E1 or a value of the first input variable E1 can be specified, and the threshold voltage V_TH-1 of the FeFET 110-1 can be programmed on the basis of the first input variable E1 or the value thereof, for example using a conventional programming method. In further exemplary embodiments, for example, a position of a characteristic curve indicating a drain current with respect to a gate-source voltage can be changed by programming 210, for example shifted along the gate-source voltage coordinate, which is shown by way of example in FIG. 11A. The curve K1 corresponds to a characteristic curve of the drain current Id with respect to a gate-source voltage Vgs for the FeFET 110-1 (FIG. 2) in a first programmed state, for example corresponding to a first value for the threshold voltage of the FeFET. The curve K2 is of the same type as the characteristic curve K1 but in a second programmed state, for example corresponding to a second value for the threshold voltage of the FeFET 110-1, which is different from the first state or first value for the threshold voltage of the FeFET 110-1. The same applies to the further curves K3, K4, each corresponding to further different programmed values for the threshold voltage of the FeFET 110-1. In other words, in further exemplary embodiments, by programming 210 (FIG. 3) the threshold voltage, an Id/Vgs characteristic curve of the FeFET 110-1 can be shifted, for example along the horizontal Vgs axis of FIG. 11A. For example, the characteristic curve K1 according to FIG. 11A can be assigned an exemplary value of “3” for the first input variable E1, and the characteristic curve K2 can be assigned an exemplary value of “2” for the first input variable E1, and the characteristic curve K3 can be assigned an exemplary value of “1” for the first input variable E1, and the characteristic curve K4 can be assigned an exemplary value of “0” for the first input variable E1.

Although the principle according to the embodiments is not limited to ferroelectric field-effect transistors (FeFETs), for the sake of clarity, and without restricting generality, the following exemplary embodiments relate primarily to field-effect transistors designed as FeFETs.

In further exemplary embodiments, FIG. 4, 5, it is provided that the method comprises: providing 220 a charging current I-L for charging 222 a capacitance C-1a associated with the gate electrode 110-1a of the first field-effect transistor 110-1, for example an intrinsic and/or parasitic capacitance, for example a Miller capacitance, for example by means of a charging device 12. As an alternative or in addition to the, for example intrinsic, Miller capacitance, in further exemplary embodiments of the gate electrode 110-1a, a further capacitance (not shown) can thus be assigned, for example for setting, for example tuning, a specifiable capacitance value.

In further exemplary embodiments, it is also possible to adjust the intrinsic capacitance within the framework of manufacturing conditions during a manufacturing process, for example of the processing device 100 (FIG. 2). In further exemplary embodiments, FIG. 4, a defined activation of the FeFET 110-1 is possible by charging 222 the above-described capacitance C-1a, i.e., for example, moving the FeFET 110-1 from a, e.g., blocking (high-impedance) state to a conductive (low-impedance) state, wherein, for example, a time behavior for the charging 222 can inter alia be determined by the aforementioned capacitance C-1a and/or an optionally present intrinsic resistance (not shown), for example of the gate electrode 110-1a.

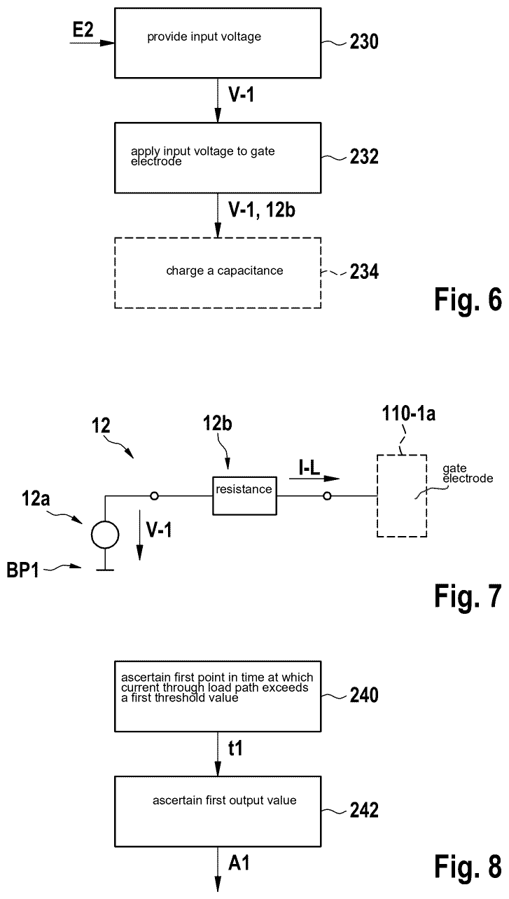

In further exemplary embodiments, FIG. 6, 7, it is provided that the method comprises: providing 230 an input voltage V-1 (e.g., by means of a voltage source 12a, see FIG. 7) on the basis of the second input variable E2; applying 232 (FIG. 6) the input voltage V-1 to the gate electrode 110-1a of the first field-effect transistor 110-1 (FIG. 2) via a specifiable resistance 12b, and, optionally, at least periodically charging 234 a, for example the, capacitance C-1a associated with the gate electrode 110-1a of the first field-effect transistor 110-1 (FIG. 2, 5). In further exemplary embodiments, the time behavior for charging the capacitance (and thus, for example, for putting the load path of the FeFET into a low-impedance state) can be set by charging via the specifiable resistance 12b. In addition, the time behavior for charging depends on the input voltage V-1, which can be selected, for example, on the basis of the second input variable E2. Reference sign 12 in FIG. 7 denotes an optional charging device, which may comprise, for example, the components 12a, 12b, and reference sign BP1 symbolizes a first electrical reference potential, for example ground potential.

In further exemplary embodiments, FIG. 8, it is provided that the method comprises: ascertaining 240 a first point in time t1, at which the current I-LS (FIG. 2, 5) through the load path 110-1-LS of the first field-effect transistor 110-1 exceeds a specifiable first threshold value (for example, considered from the charging 222 of the capacitance C-1a associated with the gate electrode 110-1a of the first field-effect transistor 110-1); ascertaining 242 the first output variable A1 on the basis of the first point in time t1.

In other words, using the principle according to the embodiments, for example, a multiplication a*b=c (* is the (“scalar”) multiplication operator) can be evaluated using the FeFET 110-1, wherein the factor a corresponds, for example, to the first input variable E1 (for example, programming 210 the FeFET 110-1 to a threshold voltage V_TH-1 corresponding to the factor a), and wherein the factor b corresponds, for example, to the second input variable E2 (for example, input voltage V-1 for charging 222 the capacitance C-1a associated with the gate electrode 110-1a of the first field-effect transistor 110-1).

For example, in further exemplary embodiments, for comparatively small values of the first factor a, a comparatively high threshold voltage V_TH-1 can be programmed for the first FeFET 110-1 so that, in a charging process considered by way of example of the capacitance associated with the gate electrode of the first FeFET, the load path 110-1-LS becomes conductive comparatively late, and the first point in time t1, at which the current I-LS through the load path of the first FeFET exceeds the specifiable first threshold value, is thus comparatively late, relative to a start of the charging process.

In contrast, in further exemplary embodiments, for comparatively large values of the first factor a, a comparatively low threshold voltage V_TH-1 can be programmed for the first FeFET 110-1 so that, in a charging process considered by way of example of the capacitance associated with the gate electrode of the first FeFET, the load path becomes conductive comparatively early, and the first point in time, at which the current through the load path of the first FeFET exceeds the specifiable first threshold value, is thus comparatively early, relative to a start of the charging process.

For example, in further exemplary embodiments, for comparatively small values of the second factor b, a comparatively low input voltage V-1 can be selected for the charging process 222 of the capacitance C-1a associated with the gate electrode 110-1a of the first FeFET 110-1, which causes a comparatively small temporal change in the gate-source voltage during the charging process and thus also causes a comparatively late exceeding of the first threshold value, for example similarly to a comparatively high threshold voltage.

For example, in further exemplary embodiments, for comparatively large values of the second factor b, a comparatively high input voltage V-1 can be selected for the charging process of the capacitance associated with the gate electrode of the first FeFET, which causes a comparatively large temporal change in the gate-source voltage during the charging process and thus also causes a comparatively early exceeding of the first threshold value, for example similarly to a comparatively low threshold voltage.

In further exemplary embodiments, a specifiable value for the result of the multiplication a*b=c, i.e., for the product c, can accordingly be assigned to the first point in time t1 (FIG. 8), at which the current I-LS through the load path 110-1-LS of the first FeFET 110-1 exceeds the specifiable first threshold value. In further exemplary embodiments, different result values for the product c can be assigned in a comparable manner to different points in time, for example calculated after the start of the charging process, so that, in further exemplary embodiments, for example on the basis of a specific value of the first point in time t1, the corresponding result value for the product c can be deduced.

In other words, in further exemplary embodiments, a time measurement can be carried out, on the basis of which the product c can be ascertained. This is advantageous in further exemplary embodiments since the time measurement can be carried out very efficiently and/or precisely with currently available technology.

Exemplary aspects of the principle according to the embodiments, which can be combined in further exemplary embodiments, for example, with at least one of the exemplary embodiments described above, are described below with reference to FIG. 11B to 11G.

FIG. 11B shows four curves K5, K6, K7, K8 by way of example, each symbolizing a time profile of a gate-source voltage Vgs of the FeFET 110-1, as can result from the charging 222 (FIG. 4) using the input voltage V-1 (FIG. 7) according to exemplary embodiments. The curve K5 is, for example, associated with a comparatively low input voltage V-1, for example corresponding to a comparatively small value of, for example, “0” for the second input variable E2; the curve K6 is, for example, associated with a higher input voltage V-1, for example corresponding to a larger value of, for example, “1” for the second input variable E2; the curve K7 is, for example, associated with an even higher input voltage V-1, for example corresponding to an even larger value of, for example, “2” for the second input variable E2; and the curve K8 is, for example, associated with an even higher input voltage V-1, for example corresponding to an even larger value of, for example, “3” for the second input variable E2. In FIG. 11B, it can be seen that the higher the input voltage V-1 is selected for the charging process 222, corresponding to a particular value for the second input variable E2, the steeper the rise in the gate-source voltage Vgs.

FIG. 11C symbolically shows the curves K5, K6, K7, K8 according to FIG. 11B and, by way of example, four further curves K9, K10, K11, K12, each corresponding to different threshold voltages for the FeFET 110-1. The curve K9, for example, corresponds to a comparatively low threshold voltage and is, by way of example, associated with the value “3” for the first input variable E1. The curve K10, for example, corresponds to a higher threshold voltage (than curve K9) and is, by way of example, associated with the value “2” for the first input variable E1. The curve K11, for example, corresponds to a higher threshold voltage (than curve K10) and is, by way of example, associated with the value “1” for the first input variable E1. The curve K12, for example, corresponds to a higher threshold voltage (than curve K11) and is, by way of example, associated with the value “0” for the first input variable E1.

In further exemplary embodiments, the FeFET 110-1 can, for example, be optionally programmed with each of the four threshold voltages K9, K10, K11, K12, which corresponds, for example, to an assignment of the relevant value “3”, “2”, “1”, “0” for the first input variable E1.

For example, it is assumed that the FeFET 110-1 is programmed to the threshold voltage according to curve K10, corresponding to the value “1” for the first input variable E1. This corresponds, by way of example, to a selection of the characteristic curve K2 according to FIG. 11D for operation of the FeFET 110-1. FIG. 11C also shows a corresponding intersection point SP, which results, for example, when the input voltage V-1 according to the curve K6 is used.

FIG. 11E is a representation similar to FIG. 11C and shows that the gate-source voltage Vgs according to curve K6 intersects the threshold voltage according to curve K10 at the point in time tr in the intersection point SP, and FIG. 11F schematically shows a time profile of a current I-LS through the load path 110-1-LS of the FeFET 110-1 in the configuration according to FIG. 11E, i.e., with the characteristic curve K2 and the input voltage V-1 according to curve K6. In FIG. 11F, it can be seen that if, for example, at the point in time t=0, the input voltage V-1 associated with curve K6 is applied to the gate electrode of the FeFET 110-1, the current I-LS through the load path 110-1-LS increases until the specifiable first threshold value Ir is reached at the point in time tr (e.g., corresponding to the first point in time t1 according to FIG. 8). In further exemplary embodiments, this point in time tr is detected, for example according to block 240 of FIG. 8, and used to ascertain the multiplication result a*b=c, as already described above.

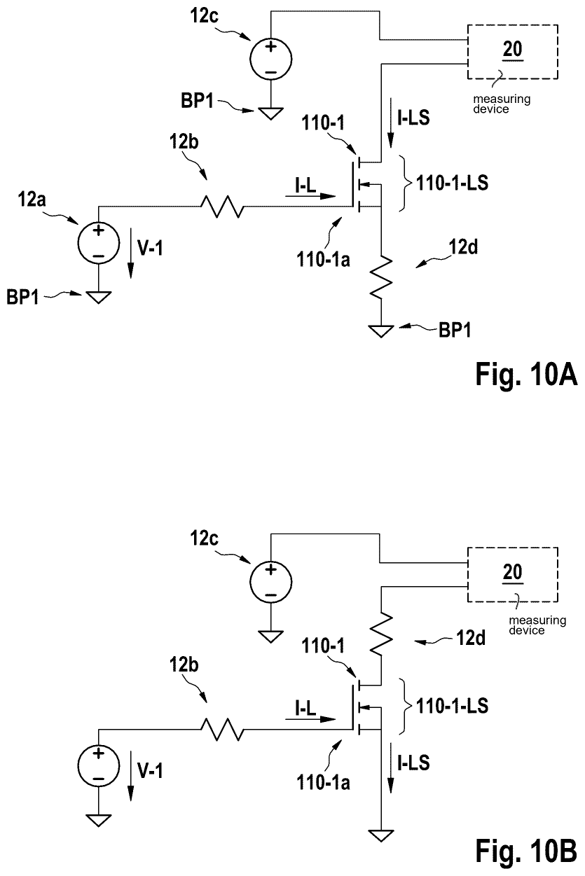

In further exemplary embodiments, the specifiable first threshold value Ir (FIG. 11F) corresponds to at least one of the following elements: a) saturation current of the first field-effect transistor 110-1; b) limit current, to which the current I-LS through the load path of the first field-effect transistor 110-1 can be limited and/or is limited, for example by means of at least one limiting resistor (see below with regard to FIG. 10A, 10B) connected in series with the load path; c) any specifiable current value. In further exemplary embodiments, a measurement of the current I-LS, for example by means of a current-based analog-to-digital converter 20 (see below, FIG. 10A), can be used to ascertain the point in time tr.

In further exemplary embodiments, FIG. 11G, for example depending on a) a distribution of possible states or threshold voltages, which can be stored in the FeFET 110-1 and characterize, for example, a possible value range of the first input variable E1, and/or b) a temporal change in the gate-source voltage Vgs associated with different input voltages V-1 (characterizing a value range of the second input variable E2), a value characterizing the, for example arithmetic, result of the multiplication a*b=c can be assigned on the time axis (see, for example, reference sign tr according to FIG. 11F), wherein the value on the time axis corresponds to a time period related to the start of the application 202 (FIG. 1) of the first control variable AG1 (e.g., corresponding to the input voltage V-1) to the gate electrode 110-1a of the first field-effect transistor 110-1. In other words, exemplary embodiments allow a time-encoded MAC calculation, wherein the result corresponds at least to the multiplication c=a*b of said time period or the value tr.

FIG. 11G shows, by way of example, possible time profiles V1 of the gate-source voltage Vgs, for example corresponding to possible values “1”, “2”, “3” for the second input variable E2, see arrow A-V1, and possible threshold voltages V2, for example corresponding to possible values “0”, “1”, “2”, “3” for the first input variable E1, see arrow A-V2, as well as corresponding time values, which characterize associated possible multiplication results c=a*b, see arrow A-t.

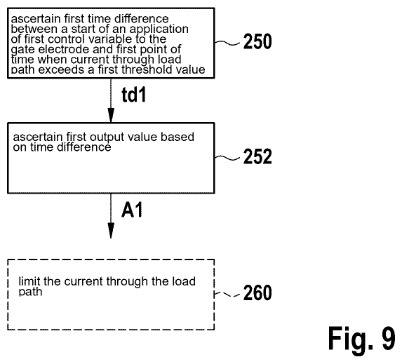

In further exemplary embodiments, FIG. 9, it is provided that the method comprises: ascertaining 250 a first time difference td1 between a start of the application 202 (FIG. 1) of the first control variable AG1 (e.g., corresponding to a start of the charging process 222, FIG. 4) to the gate electrode 110-1a of the first field-effect transistor 110-1 and the first point in time t1 (cf. also point in time t1 according to FIG. 11F), at which the current I-LS through the load path of the first field-effect transistor exceeds the specifiable first threshold value; and ascertaining 252 the first output variable A1 on the basis of the first time difference td1, for example using an assignment of possible time differences to possible multiplication results c=a*b.

In further exemplary embodiments, FIG. 9, it is provided that the method comprises: limiting 260 the current I-LS through the load path of the first field-effect transistor by means of at least one limiting resistor connected in series with the load path (or a load path of a transistor operable as a resistor, for example FETs), see FIG. 10A, 10B below. The optional limiting 260 can, for example, take place during the application 202 (FIG. 1) or the charging process 222 (FIG. 4).

FIG. 10A schematically shows a simplified circuit diagram according to further exemplary embodiments. The first FeFET 110-1 is shown with the assigned charging device 12. Element 12c symbolizes an optional voltage supply; element 12d symbolizes the limiting resistor mentioned above, which is connected here between the load path 110-1-LS and the first reference potential BP1. Element 20 symbolizes a measuring device, for example a, for example current-based, analog-to-digital converter 20, for ascertaining, for example, the first variable G1, for example the current I-LS.

In further exemplary embodiments, FIG. 10A, the limiting resistor 12d can be selected, for example, such that, for example in the switched-on state of the FeFET 110-1, the current I-LS through the load path 110-1-LS is between, for example about, 10 nA (nanoamperes) and, for example about, 1000 nA, for example about 100 nA. This causes, for example, the current I-LS through the load path of the first FeFET to increase from, for example, 0 to the aforementioned 100 nA during the charging process, with a time behavior determined by the two input variables E1, E2 or the configuration based thereon (e.g., programming of the threshold voltage V_TH-1 of the FeFET 110-1, selection of the input voltage V-1 for charging).

FIG. 10B schematically shows a simplified circuit diagram according to further exemplary embodiments. The exemplary configuration according to FIG. 10B differs from the exemplary configuration according to FIG. 10A in that the limiting resistor 12d in FIG. 10B is arranged between the analog-to-digital converter 20 and the load path 110-1-LS.

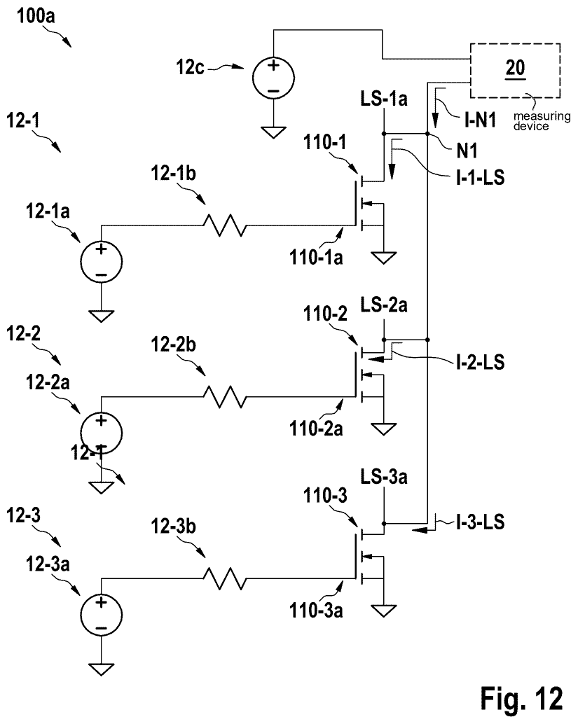

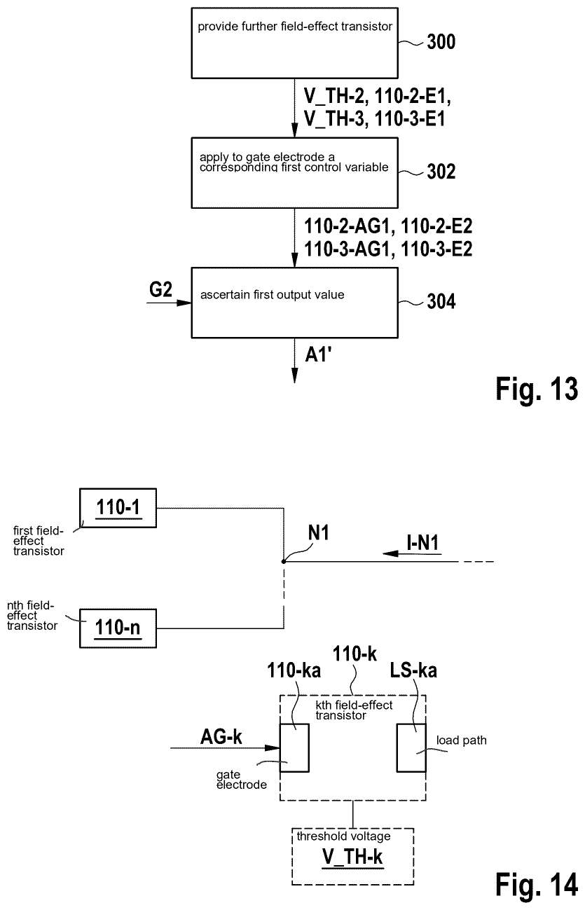

In further exemplary embodiments, FIG. 12, 13, it is provided that the processing device 100a has at least one further field-effect transistor, for example a ferroelectric field-effect transistor, in the present case according to FIG. 12, for example, a total of three FeFETs 110-1, 110-2, 110-3, wherein a corresponding first terminal LS-1a, LS-2a, LS-3a of a load path (drain-source path) of the first field-effect transistor 110-1 and of the at least one further field-effect transistor 110-2, 110-3 is connected to a first circuit node N1, wherein the method comprises: providing 300 (FIG. 13) the at least one further field-effect transistor 110-2, 110-3 with a corresponding further threshold voltage V_TH-2, V_TH-3, which characterizes a first input variable 110-2-E1, 110-3-E1 associated with the corresponding further field-effect transistor 110-2, 110-3; applying 302 to a corresponding gate electrode 110-2a, 110-3a of the at least one further field-effect transistor 110-2, 110-3 a corresponding first control variable 110-2-AG-1, 110-3-AG-1, which characterizes a second input variable 110-2-E2, 110-3-E2 associated with the corresponding further field-effect transistor 110-2, 110-3; ascertaining 304 the first output variable A1′, which characterizes, for example, a sum of respective products 110-2-E1*110-2-E2, 110-3-E1*110-3-E2 of the corresponding first input variable and the corresponding second input variable, on the basis of a second variable G2, which characterizes a time profile of a current I-N1 associated with the first circuit node N1, wherein, for example, the second variable G2 is at least one of the following elements: a) the current I-N1 itself associated with the first circuit node N1; b) a voltage which can be ascertained on the basis of at least the current associated with the first circuit node. In further exemplary embodiments, a calculation of the MAC (multiply and accumulate) type is, for example, thereby made possible, wherein the first field-effect transistor 110-1 and the at least one further, for example second or third, field-effect transistor 110-2, 110-3 in each case carry out, for example, a multiplication, for example analogously to the embodiments described above by way of example. An accumulation, for example addition, is carried out in the present case, for example, by connecting the respective load paths LS-2a, LS-3a of the two further field-effect transistors 110-2, 110-3 (just like by connecting the load path LS-1a of the first field-effect transistor 110-1) to the first circuit node N1, for example, by adding the currents I-1-LS, I-2-LS, I-3-LS through the load paths of the field-effect transistors connected to the first circuit node N1.

For example, in the aforementioned configuration 100a according to FIG. 12, a first product c1=a1*b1 can be ascertained by the first field-effect transistor 110-1 on the basis of the factors a1, b1 (which can, for example, be realized by programming a corresponding threshold voltage and/or specifying a corresponding input voltage for charging, e.g., the intrinsic capacitance of the first field-effect transistor), and a second product c2=a2*b2 can be ascertained by the second field-effect transistor 110-2 on the basis of the factors a2, b2 (which can, for example, be realized by programming a corresponding threshold voltage and/or specifying a corresponding input voltage for charging, e.g., the intrinsic capacitance of the second field-effect transistor), and a third product c3=a3*b3 can be ascertained by the third field-effect transistor 110-3 on the basis of the factors a3, b3 (which can, for example, be realized by programming a corresponding threshold voltage and/or specifying a corresponding input voltage for charging, e.g., the intrinsic capacitance of the third field-effect transistor), wherein an accumulation, for example addition, c1+c2+c3 can be carried out by the combination of the respective load currents I-1-LS, I-2-LS, I-3-LS through the load paths of the three field-effect transistors 110-1, 110-2, 110-3 in the first circuit node N1. Even in the exemplary embodiments with more than one field-effect transistor 110-1, the result c1+c2+c3 of the MAC calculation can be deduced on the basis of the second variable G2 and a possibly effected assignment of points in time at which one or more corresponding threshold values are exceeded by the second variable.

In further exemplary embodiments, FIG. 12, the first FeFET 110-1 is assigned a first charging device 12-1 comprising, for example, a voltage source 12-1a and a resistor 12-1b, in order to charge a, for example intrinsic, capacitance (see also reference sign C-1a of FIG. 2) associated with the gate electrode 110-1a of the first FeFET 110-1, for example with a defined, for example RC, time constant, for example in the sense of the application 202 according to FIG. 1 and/or the application 302 according to FIG. 13. In a further exemplary embodiment, this results in a time profile of the current I-1-LS through the load path of the first FeFET 110-1 corresponding to the input variables E1, E2 (e.g., specifiable by selecting the input voltage V-1 and/or programming the first FeFET 110-1) associated with the first FeFET 110-1, which time profile contributes to the current I-N1, thus, for example, providing a first summand for the MAC calculation which can be evaluated on the basis of the second variable G2.

In further exemplary embodiments, FIG. 12, the second FeFET 110-2 is assigned a second charging device 12-2 comprising, for example, a voltage source 12-2a and a resistor 12-2b, in order to charge a, for example intrinsic, capacitance (e.g., similar to reference sign C-1a of FIG. 2) associated with the gate electrode 110-2a of the second FeFET 110-2, for example with a defined, for example RC, time constant, for example in the sense of the application 202 according to FIG. 1 and/or the application 302 according to FIG. 13. In a further exemplary embodiment, this results in a time profile of the current I-2-LS through the load path of the second FeFET 110-2 corresponding to the input variables E1, E2 (e.g., specifiable by selecting the input voltage V-1 and/or programming the second FeFET 110-2) associated with the second FeFET 110-2, which time profile contributes to the current I-N1, thus, for example, providing a second summand for the MAC calculation which can be evaluated on the basis of the second variable G2.

In further exemplary embodiments, FIG. 12, the third FeFET 110-3 is assigned a third charging device 12-3 comprising, for example, a voltage source 12-3a and a resistor 12-3b, in order to charge a, for example intrinsic, capacitance (e.g., similar to reference sign C-1a of FIG. 2) associated with the gate electrode 110-3a of the third FeFET 110-3, for example with a defined, for example RC, time constant, for example in the sense of the application 202 according to FIG. 1 and/or the application 302 according to FIG. 13. In a further exemplary embodiment, this results in a time profile of the current I-3-LS through the load path of the third FeFET 110-3 corresponding to the input variables E1, E2 (e.g., specifiable by selecting the input voltage V-1 and/or programming the third FeFET 110-2) associated with the third FeFET 110-3, which time profile contributes to the current I-N1, thus, for example, providing a third summand for the MAC calculation which can be evaluated on the basis of the second variable G2.

In further exemplary embodiments, for at least two of the FeFETs 110-1, 110-2, 110-3 of the processing device 100a according to FIG. 12, identical or different, for example RC, time constants for charging the corresponding gate electrode can be provided in each case.

In further exemplary embodiments, FIG. 12, at least one of the FeFETs 110-1, 110-2, 110-3 can be assigned a limiting resistor (not shown in FIG. 12, see, e.g., element 12d according to FIG. 10A).

In further exemplary embodiments, the principle according to the embodiments described above with reference to FIG. 12 by way of example using three FeFETs 110-1, 110-2, 110-3 is applicable to processing devices having more than three field-effect transistors, for example FeFETs.

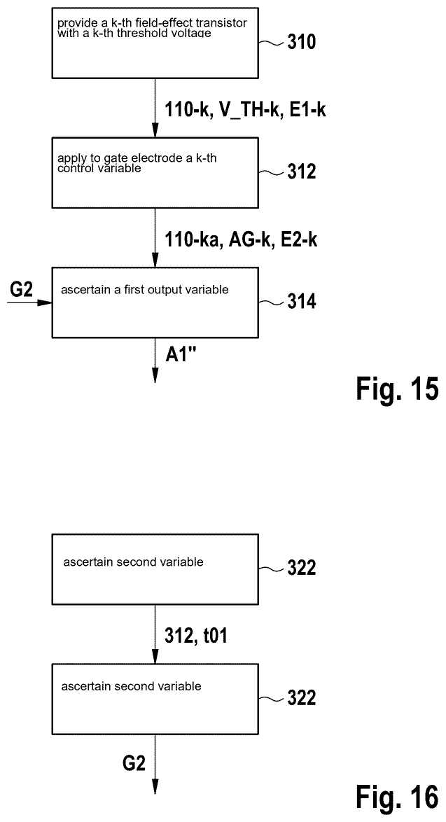

In further exemplary embodiments, FIG. 14, 15, it is thus provided that the processing device has n, n>1, field-effect transistors, for example FeFETs, 110-1, . . . , 110-n, wherein a corresponding first terminal of a load path of the n field-effect transistors is connected to a circuit node, for example the first circuit node N1 (see also FIG. 12), wherein the method comprises: providing 310 a k-th field-effect transistor, k=1, . . . , n, (for example all n field-effect transistors) with a k-th threshold voltage V_TH-k (for example by optional programming, e.g., in the case of FeFETs), which characterizes a corresponding first input variable E1-k associated with the k-th field-effect transistor 110-k; applying 312 to a gate electrode 110-ka (FIG. 14) of the k-th field-effect transistor 110-k (for example of all n field-effect transistors) a k-th control variable AG-k, which characterizes a corresponding second input variable E2-k associated with the k-th field-effect transistor 110-k; ascertaining 314 the first output variable A1″, which characterizes, for example, a sum of k (for example k=n) products of the corresponding first input variable E1-k and the corresponding second input variable E2-k, on the basis of a or the second variable G2, which characterizes the time profile of the current I-N1 associated with the first circuit node N1. In further exemplary embodiments, the second variable results, for example, from the individual currents, each of which flows through the corresponding load path LS-ka of a k-th FeFET on the basis of the associated input variables E1-k, E2-k, for example during the application 312 (FIG. 15).

In further exemplary embodiments, the principle according to the embodiments can thus be extended to any number n of field-effect transistors so that, for example, MAC calculations are possible. which makes possible a formation of, for example maximally, n products and an accumulation of the, for example maximally, n products. In further exemplary embodiments, such calculations can be used, for example, for the evaluation (inference) of artificial (deep) neural networks ((D)NN). Further possible applications according to further exemplary embodiments are described below with reference to FIG. 22.

In further exemplary embodiments, FIG. 16, it is provided that the method comprises: starting 320 the application 312 of the k-th control variable Ag-k to the gate electrode 110-ka of the k-th field-effect transistor 110-k (for example of all n field-effect transistors 110-1, . . . , 110-n) at a starting point in time t01 (for example common to all n field-effect transistors); repeatedly, for example periodically, for example continuously, ascertaining 322 the second variable G2, for example during a specifiable time period from the starting point in time t01.

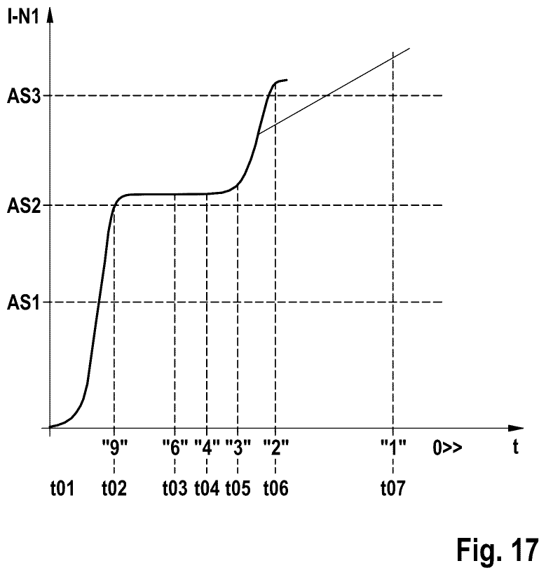

In this regard, FIG. 17 schematically shows a time profile of the current I-N1 through the first circuit node N1, as can result, for example, in a processing device 100a according to FIG. 12 with three FeFETs 110-1, 110-2, 110-3, and assigned result values “9”, “6”, “4”, “3”, “2”, “1” at associated points in time t02, t03, t04, t05, t06, t07 according to exemplary embodiments. For example, it can be seen in FIG. 17 that the current I-N1 increases comparatively sharply between the starting point in time t01 and the point in time t02, for example according to two of three possible amplitude levels AS1, AS2, AS3, cf. the vertical axis, there the value AS2, which, for example, results from the fact that two of the three FeFETs according to FIG. 12 have changed from their blocking state to their conductive state within the time interval (t01, t02). If, for example, a current through the load path of the FeFETs according to FIG. 12 is limited to a default value of, for example, 100 nA, for example by means of a corresponding limiting resistor 12d, see FIG. 10A, not shown in FIG. 12 for reasons of clarity, an amplitude level AS1 or a difference AS2−AS1, AS3−AS2 between two adjacent amplitude levels will, for example, correspond to the exemplary 100 nA.

The exemplary current rise in the time interval (t01, t02) can thus be interpreted as a contribution 2*9 to the result of the MAC calculation, wherein the value 9 results from the assignment of the value “9” to the point in time t02 (reaching the second amplitude level AS2), and wherein the factor “2” results from the fact that the current rise in the time interval (t01, t02) corresponds to two amplitude levels, i.e., from zero to AS2.

A further current rise takes place according to FIG. 17 only later in a time interval (t05, t06), namely by one amplitude level, i.e., to the maximum possible third amplitude level AS3 in the present case (for example, due to a limitation of the current through all three FeFETs 110-1, 110-2, 110-3 to 100 nA in each case). The exemplary current rise in the time interval (t05, t06) can thus be interpreted, for example, as a contribution 1*2 to the result of the MAC calculation, wherein the value 2 results from the assignment of the value “2” to the point in time t06 (reaching the third amplitude level AS3), and wherein the factor “1” results from the fact that the current rise in the time interval (t05, t06) corresponds to one amplitude level, i.e., from AS2 to AS3.

In further exemplary embodiments, the result of the MAC calculation can thus be interpreted as 2*9+1*2=20.

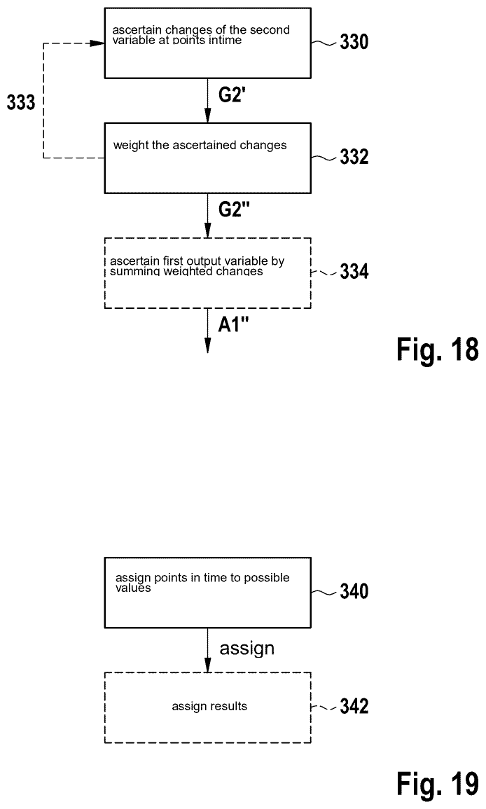

In further exemplary embodiments, FIG. 18, it is provided that the method comprises: ascertaining 330 changes G2′ of the second variable G2 at specifiable points in time (see, e.g., the change between the amplitude levels AS0, AS2, AS3 according to FIG. 17), wherein, for example, the specifiable points in time are in each case associated with possible values for the corresponding first input variable and/or for the corresponding second input variable (see, e.g., the value “9”, which is associated with the point in time t02 according to FIG. 17); weighting 332 the ascertained changes G2′ of the second variable G2, wherein weighted changes G2″ are obtained; and, optionally, ascertaining 334 the first output variable A1″ by summing the weighted changes G2″ of the second variable G2.

In further exemplary embodiments, changes which are associated with a transition of at least one of the used field-effect transistors from a high-impedance state to a low-impedance state can, for example, thus be considered changes G2′ of the second variable G2 which are to be ascertained. If, for example, a maximum current through a load path of at least one of the transistors used is 100 nA, then, in further exemplary embodiments, a change in the second variable in the range of approximately 100 nA can be taken into account, see, for example, the amplitude levels AS1, AS2, AS3 according to FIG. 17. In further exemplary embodiments, changes in the second variable G2, which, for example, are significantly less than 100 nA, can remain disregarded, for example if none of the field-effect transistors used has a correspondingly lower maximum current than the 100 nA mentioned.

In further exemplary embodiments, FIG. 18, it is provided that the method comprises: repeating 333 the ascertainment 330 and the weighting 332, for example until a specifiable termination criterion is met.

In further exemplary embodiments, the termination criterion is an elapsing of a specifiable maximum measuring time, for example specifiable on the basis of a number of field-effect transistors used and/or on the basis of the corresponding first and/or second input variable of at least one of the field-effect transistors used.

In further exemplary embodiments, the termination criterion depends on a time profile of the gate-source voltage of a field-effect transistor having the smallest slope (e.g., due to a comparatively high threshold voltage (e.g., corresponding to a comparatively small first input variable E1) and/or due to a comparatively low input voltage (e.g., corresponding to a comparatively small second input variable E2)).

In further exemplary embodiments, the termination criterion is met when the second variable G2 has a maximum value dependent, for example, on the configuration (for example, number of field-effect transistors) of the processing device (for example, maximum current at the first node corresponds, for example, to a state in which all field-effect transistors are low-impedance). In FIG. 12, 17, this corresponds, for example, to the three FeFETs 110-1, 110-2, 110-3 and the maximum of three different non-vanishing amplitude levels AS1, AS2, AS3 of FIG. 17.

In further exemplary embodiments, FIG. 19, it is provided that the method comprises: assigning 340 the specifiable points in time t02, t03, . . . (FIG. 17) (for example, associated with the changes in the second variable G2) to possible values “9”, “6”, . . . for the corresponding first input variable and/or for the corresponding second input variable. In this case, according to FIG. 19, for example, the assignment ASSIGN results, which can optionally be used in the future for carrying out MAC calculations; see the optional block 342.

In further exemplary embodiments, the first and/or second input variable E1, E2 of at least one field-effect transistor, for example FeFET, for example some, for example all, field-effect transistors, for example FeFETs, can be changed, for example dynamically (during operation). Changing the first input variable(s) for one or more FeFETs can be done, for example, by the programming described above, for example reprogramming. Changing the first input variable(s) for one or more FeFETs can be done, for example, by reconfiguring (or replacing) the relevant charging device 12, whereby, for example, other values for the input voltage V-1 (FIG. 7) can be specified. In further exemplary embodiments, at least one charging device 12, 12-1, 12-2, 12-3 can have, for example, a controllable voltage source (not shown) in order to specify other values for the input voltage V-1 in the sense of a change in the second input variable.

In further exemplary embodiments, even a value of zero, i.e., c=0, can occur as a result of a multiplication a*b=c, for example when at least one of the factors a, b is zero, i.e., a=0 and/or b=0.

By way of example, the factor a (corresponding to the first input variable E1) can have the value zero if the threshold voltage of the relevant FeFET is programmed to such a high value that a time profile of the gate-source voltage during the application 202, 302, 312, i.e., during charging of the capacitance C-1a (FIG. 2), does not reach the programmed high threshold voltage within a measurement period, i.e., before the end of a relevant measurement.

By way of example, the factor b (corresponding to the second input variable E2) can have the value zero if the input voltage V-1 has the value zero. In that case, there is no charging of the capacitance C-1a, and the relevant FeFET becomes (for example, not at all) conductive and will thus also not provide a current contribution during a measurement.

In further exemplary embodiments, the assignment ASSIGN, for example according to block 340 of FIG. 19, can also take into account the possible occurrence of vanishing, i.e., zero-valued, input variables E1 and/or E2 or a and/or b, see also, for example, the time period t>t07 of FIG. 17.

Further exemplary embodiments, FIG. 2, relate to a device 1000 for carrying out the method according to the embodiments.

In further exemplary embodiments, FIG. 2, it is provided that the device 1000 has a processing device 100 having at least one first field-effect transistor 110-1, for example a ferroelectric field-effect transistor, wherein, for example, the processing device has n, n>1, field-effect transistors, for example ferroelectric field-effect transistors (see, e.g., FIG. 12, 14).

In further exemplary embodiments, FIG. 2, it is provided that the device 1000 has an optional programming device 10 for programming 210 (FIG. 3) the at least one first field-effect transistor, for example FeFET, to a specifiable threshold voltage. In further exemplary embodiments, for example having a plurality of, for example n, FeFETs, the optional programming device 10 can be designed, for example, for programming, for example reprogramming, at least one FeFET, for example some, for example all, FeFETs.

In further exemplary embodiments, FIG. 2, it is provided that the device 1000 has at least one charging device 12 for providing a charging current I-L (FIG. 5) for the at least one first field-effect transistor, for example for a plurality of, for example all, field-effect transistors. A plurality of identical or different charging devices 12-1, 12-2, 12-3 are also possible in further exemplary embodiments, FIG. 12.

In further exemplary embodiments, FIG. 2, it is provided that the device 1000 has at least one measuring device 20, for example a, for example current-based, analog-to-digital converter, for ascertaining at least one of the following variables: a) first variable; b) second variable. If the first and/or second variable is present in the form of an electrical voltage U-I-LS, for example the measuring device 20 can also be designed as an analog-to-digital converter for converting the electrical voltage U-I-LS into a digital (time- and/or value-discrete) signal.

In further exemplary embodiments, FIG. 2, it is provided that the device 1000 comprises a control device 400, which is designed to execute at least one of the following elements: a) control of at least one component (for example, 10 and/or 12 and/or 20) of the device 1000; b) execution of at least one aspect of the method according to the embodiments.

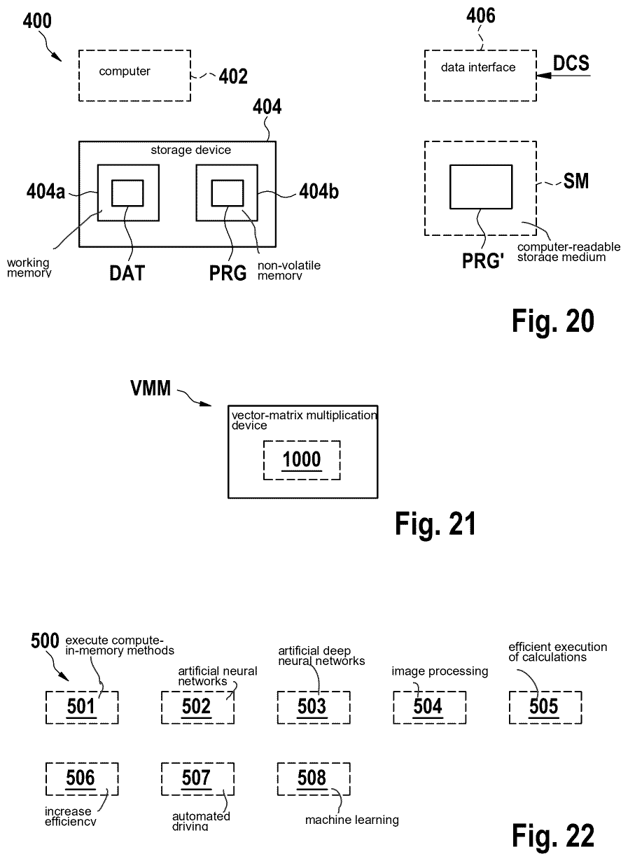

FIG. 20 shows, by way of example, a configuration of the control device 400 according to further exemplary embodiments.

By way of example, the control device 400 comprises: a computing device (“computer”) 402 having at least one computing core (not shown); a storage device 404 assigned to the computing device 402 for at least temporarily storing at least one of the following elements: a) data DAT (for example, data associated with at least one component of the device 1000 or of the processing device 100, for example, possible values for the first input variable E1 and/or possible values for the second input variable E2 and/or an assignment ASSIGN, and/or data relating to the current configuration (for example, characterizing how the FeFETs are currently programmed and/or which values are currently being provided for the input voltages V-1); b) computer program PRG, for example for carrying out the method according to the embodiments.

In further exemplary embodiments, the storage device 404 has a volatile memory (for example, working memory (RAM)) 404a, and/or a non-volatile memory (NVM) (for example, flash EEPROM) 404b, or a combination thereof or with other memory types not explicitly mentioned.

Alternatively, the control device 400 can also be designed, for example, as an ASIC (application-specific integrated circuit) and/or as a programmable logic circuit, for example FPGA, and/or as a microcontroller and/or as a digital signal processor and/or as an accelerator circuit, for example for matrix calculation operations, and/or as, for example, a pure hardware circuit, for example a digital circuit, and/or have at least one of these elements.

Further exemplary embodiments, FIG. 20, relate to a computer-readable storage medium SM comprising commands PRG that, when executed by a computer 402, cause said computer to carry out the method according to the embodiments.

Further exemplary embodiments relate to a computer program PRG comprising commands that, when the program PRG is executed by a computer 402, cause said computer to carry out the method according to the embodiments.

Further exemplary embodiments relate to a data carrier signal DCS that characterizes and/or transmits the computer program PRG according to the embodiments. The data carrier signal DCS can be received, for example, via an optional data interface 406 of the device 400.

Further exemplary embodiments, FIG. 21, relate to a computing device, for example a vector-matrix multiplication device VMM, comprising at least one device 1000 according to the embodiments.

Further exemplary embodiments, relate to a use 500 of the method according to the embodiments and/or of the device 1000 according to the embodiments and/or of the computing device VMM according to the embodiments for at least one of the following elements: a) execution 501 of compute-in-memory methods, for example with weights and/or input variables E1, E2, which can, for example, in each case have a plurality of bits; b) artificial neural networks 502, for example artificial deep neural networks 503; c) image processing 504; d) efficient execution 505 of calculations; e) increasing 506 an efficiency for the execution of calculations; f) automated driving 507; g) machine learning 508, for example inference.

The principle according to the embodiments allows and/or favors at least one of the following aspects and/or advantages in further exemplary embodiments:
a) use of field-effect transistors which can represent or assume a plurality of different states, for example FeFETs which are programmable to different states, for example threshold voltages (and/or other types of memories such as PCM (phase change memory) memories, for example for MAC calculations, for example for compute-in-memory methods,
b) use of two aspects with regard to a calculation or measurement: a1) time, a2) amplitude (for example output variable of the measuring device 20), wherein, for example, a precise time measurement is efficiently possible, wherein, for example, the measuring device 20 cannot be designed to be comparatively fast in some exemplary embodiments,
c) efficient time measurement, for example by means of a timer, wherein, for example, resolutions in the GHz range, for example in the range of nanoseconds or shorter, are possible,
d) the principle according to the embodiments is scalable, for example to other resolutions,
e) in some exemplary embodiments, for example, an analog-to-digital converter can be used, which has a thermometer coding (other codings are also possible in further exemplary embodiments), which, in further exemplary embodiments, allows, for example, a comparatively simple assignment of amplitude values and measured values or result values, and optionally an adjustable step size,
f) in some exemplary embodiments, a resolution of the analog-to-digital converter can be comparatively low, for example not greater than a number of different possible memory elements or field-effect transistors (e.g., although the memory elements or field-effect transistors in exemplary embodiments can each store multi-bit values),
g) comparatively large contributions to a result of the MAC calculation occur comparatively early during a measurement period so that, for example, a measurement can be shortened, for example at the expense of precision, if, for example, the first variable G1 or the second variable G2 is evaluated only for a part of a nominal measurement period which offers the maximum possible precision.

### SPONSORSHIP AND SUPPORT INFORMATION

The project that has led to this application was sponsored by the joint venture ECSEL (JU) within the framework of sponsorship agreement no. 826655. The JU is supported by the research and innovation program Horizon 2020 of the European Union and Belgium, France, Germany, the Netherlands, Switzerland.

1-23. (canceled)

24. A method for processing input variables using a processing device having at least one first field-effect transistor, the method comprising:
providing the first field-effect transistor with a first threshold voltage, which characterizes a first input variable associated with the first field-effect transistor;
applying to a gate electrode of the first field-effect transistor a first control variable, which characterizes a second input variable associated with the first field-effect transistor;
ascertaining a first output variable, which characterizes at least one product of the first input variable and the second input variable, based on a first variable which characterizes a time profile of a current through a load path of the first field-effect transistor.

25. The method according to claim 24, wherein each of the at least one first field-effect transistor is a ferroelectric field-effect transistor.

26. The method according to claim 24, wherein the first variable is at least one of the following elements: a) the current through the load path itself; b) a voltage which can be ascertained based on at least the current through the load path.

27. The method according to claim 24, further comprising:
programming the first field-effect transistor to the first threshold voltage based on the first input variable, using a programming device, and using the programmed first field-effect transistor.

28. The method according to claim 24, further comprising:
providing a charging current for charging a capacitance associated with the gate electrode of the first field-effect transistor, the capacitance being an intrinsic and/or parasitic capacitance.

29. The method according to claim 24, further comprising:
providing an input voltage based on the second input variable;
applying the input voltage, via a specifiable resistance, to the gate electrode of the first field-effect transistor; and
at least periodically charging a capacitance associated with the gate electrode of the first field-effect transistor.

30. The method according to claim 24, further comprising:
ascertaining a first point in time, at which the current through the load path of the first field-effect transistor exceeds a specifiable first threshold value; and
ascertaining the first output variable based on the first point in time.

31. The method according to claim 30, wherein the specifiable first threshold value corresponds to at least one of the following elements: a) saturation current of the first field-effect transistor, b) limit current, to which the current through the load path of the first field-effect transistor can be limited and/or is limited using at least one limiting resistor connected in series with the load path, c) any specifiable current value.

32. The method according to claim 24, further comprising:
ascertaining a first time difference between a start of the application of the first control variable to the gate electrode of the first field-effect transistor, and a first point in time at which the current through the load path of the first field-effect transistor exceeds a specifiable first threshold value; and
ascertaining the first output variable based on the first time difference.

33. The method according to claim 24, further comprising:
limiting the current through the load path of the first field-effect transistor using at least one limiting resistor connected in series with the load path.

34. The method according to claim 24, wherein the processing device has at least one further field-effect transistor, wherein the first terminal of the load path of the first field-effect transistor and a further first terminal of a load path of the at least one further field-effect transistor are connected to a first circuit node, wherein the method further comprises:
providing the at least one further field-effect transistor with a corresponding further threshold voltage, which characterizes a corresponding first input variable associated with the corresponding further field-effect transistor;
applying to a corresponding gate electrode of the at least one further field-effect transistor a corresponding first control variable, which characterizes a corresponding second input variable associated with the corresponding further field-effect transistor;
ascertaining the first output variable, which characterizes a sum of respective products of the corresponding first input variable and of the corresponding second input variable, based on a second variable, which characterizes a time profile of a current associated with the first circuit node;
wherein the second variable is at least one of the following elements: a) the current itself associated with the first circuit node; b) a voltage which can be ascertained based on at least the current associated with the first circuit node.

35. The method according to claim 24, wherein the processing device has n, n>1, field-effect transistors, wherein a corresponding first terminal of a load path of each of the n field-effect transistors is connected to a first circuit node, wherein the method further comprises:
providing each k-th field-effect transistor, k=1, . . . , n, with a k-th threshold voltage, which characterizes a corresponding first input variable associated with the k-th field-effect transistor;
applying to a gate electrode of each k-th field-effect transistor a k-th control variable, which characterizes a corresponding second input variable associated with the k-th field-effect transistor;
ascertaining the first output variable, which characterizes a sum of k products of the corresponding first input variable and the corresponding second input variable, based on a second variable, which characterizes a time profile of current associated with the first circuit node.

36. The method according to claim 35, further comprising:
starting the application of the k-th control variable to the gate electrode of the k-th field-effect transistor at a starting point in time;
repeatedly ascertaining the second variable during a specifiable time period from the starting point in time.

37. The method according to claim 36, further comprising:
ascertaining changes of the second variable at specifiable points in time, wherein the specifiable points in time are each associated with possible values for the corresponding first input variable and/or for the corresponding second input variable;
weighting the ascertained changes of the second variable, wherein weighted changes are obtained; and
ascertaining the first output variable by summing the weighted changes of the second variable.

38. The method according to claim 37, further comprising:
repeating the ascertainment of the changes and the weighting until a specifiable termination criterion is met.

39. The method according to claim 37, further comprising:
assigning the specifiable points in time to possible values for the corresponding first input variable and/or for the corresponding second input variable.

40. A device configured to perform a method of processing input variables using a processing device having at least one first field-effect transistor, the method comprising:
providing the first field-effect transistor with a first threshold voltage, which characterizes a first input variable associated with the first field-effect transistor;
applying to a gate electrode of the first field-effect transistor a first control variable, which characterizes a second input variable associated with the first field-effect transistor;
ascertaining a first output variable, which characterizes at least one product of the first input variable and the second input variable, based on a first variable which characterizes a time profile of a current through a load path of the first field-effect transistor.

41. The device according to claim 40, wherein the device comprises the processing device having at least n>1 field-effect transistors.

42. The device according to claim 40, further comprising a programming device configured to program the at least one first field-effect transistor to a specifiable threshold voltage.

43. The device according to claim 42, further comprising at least one charging device configured to provide a charging current for the at least one first field-effect transistor.

44. The device according to claim 43, further comprising at least one measuring device including a current-based, analog-to-digital converter, configured to ascertain at least one of the following variables: a) the first variable; b) a second variable.

45. The device according to claim 42, further comprising a control device, which is configured to execute at least one of the following elements: a) control of at least one component of the device; b) execution of at least one aspect of the method.

46. The device according to claim 40, wherein the device is part of a vector matrix multiplication device.

47. The method according to claim 24, wherein the method is used for at least one of the following elements: a) execution of compute-in-memory methods, with weights and/or input variables, which can, in each case have a plurality of bits; b) artificial neural networks; c) image processing; d) efficient execution of calculations; e) increasing an efficiency for the execution of calculations; f) automated driving; g) machine learning.
